(19) United States
(12) Patent Application Publication
(10) Pub. No.: US 2013/0169300 A1
(43) Pub. Date: Jul. 4, 2013

(54) MULTI-CHIP PROBER, CONTACT POSITION CORRECTION METHOD THEREOF, AND READABLE RECORDING MEDIUM

(71) Applicants: Sharp Kabushiki Kaisha, Osaka (JP); Sun-S, Co., Ltd., Hiroshima (JP)

(72) Inventors: Shinji ISHIKAWA, Osaka (JP); Tetsuya SATO, Osaka (JP); Ren UCHIDA, Osaka (JP); Hirokazu TOKUMO, Hiroshima (JP); Takayuki NISHI, Hiroshima (JP); Tadashi YOSHIMOTO, Hiroshima (JP)

(73) Assignees: SUN-S, CO., LTD., Hiroshima (JP); SHARP KABUSHIKI KAISHA, Osaka (JP)

(21) Appl. No.: 13/729,577

(22) Filed: Dec. 28, 2012

(30) Foreign Application Priority Data
Dec. 28, 2011 (JP) 2011-287953

(51) Int. Cl. G01R 1/04

(52) U.S. Cl. CPC G01R 1/0491
USPC 324/750.22

(57) ABSTRACT

Three axial coordinate positions and the rotational position of electrode pads of chips to be inspected on a moving platform are controlled in such a manner that the electrode pads will correspond to the tip position of a plurality of probes, a large number of probes of a probe card, and electrode pads of a large number of chips, whose positional accuracy after being cut is uneven, can be positioned with accuracy, thus largely increasing the number of chips for simultaneous contact, and thus increasing the efficiency for the test.

This nonprovisional application claims priority under 35 U.S.C. §119(a) to Patent Application No. 2011-287953 filed in Japan on Dec. 28, 2011, the entire contents of which are hereby incorporated by reference.

### BACKGROUND OF THE INVENTION

1. Field of the Invention

The present invention relates to: a multi-chip prober for testing a predetermined number of a plurality of chips, having an adhesion tape attached on one side thereof, in a state where the chips are cut off from a semiconductor wafer; a contact position correction method thereof; and a computer-readable, readable recording medium on which a control program is stored, the control program describing a processing order for allowing a computer to execute respective steps of the contact position correction method.

2. Description of the Related Art

In a conventional semiconductor manufacture step, a variety of kinds of processing are performed on a thin, plate-shaped semiconductor wafer to form a plurality of devices (chips) in the semiconductor wafer. Then, the electric characteristics of each of the devices are inspected. Such devices (chips) include, not only devices of a high degree of integration, such as a bulk memory, but also devices of a simple configuration, such as a transistor and a light emitting diode (LED). Such devices of a simple configuration are often small devices of 0.2 mm to 0.5 mm square (a quadrilateral with sides ranging from 0.2 mm to 0.5 mm), with high pressure resistance and high output power. Thus, it is not possible to perform accurate inspection if the chips are in a state of a semiconductor wafer. For this reason, such a semiconductor chip is cut into individual chips using a dicer or a scriber, and various kinds of inspection are then performed on the individual chips.

For the separation of chips from a semiconductor wafer, the semiconductor wafer is first attached on a stretchable adhesion tape attached on a back surface of a plate-like frame with holes. Next, grooves are formed in the semiconductor wafer using a dicer. Then, the semiconductor wafer is cut using a scriber to be separated into individual chips. The respective chips are attached on the adhesion tape in a state where the chips are cut and separated from one another. With regard to the position of the chips on the adhesion tape, the adhesion tape is stretched and the space in between chips is widened. For that reason, the space between the chips varies, and thus the chips are not arranged in an accurate and regular manner.

An inspection for devices (chips), such as LED chips, performed under such a state will be explained hereinafter.

In order to perform an accurate optical inspection or an accurate inspection of performance tests of LED chips, LED chips are divided into individual chips and each LED chip is tested by allowing a needle to contact with an electrode pad of the LED chip. At this stage, characteristics of the output light needs to be inspected together with electrical characteristics of the LED chip.

In this case, a needle having a plurality of position adjustment mechanisms is used, and the inspection is performed by adjusting the tip position of the needle so as to correspond to the position of the electrode pad of each of the plurality of detected LED chips, and allowing the needle to come in contact with each of the chips. This technique is disclosed in Patent Document 1.

FIG. 12 is a diagram showing an exemplary configuration of a needle head and an optical detection unit part of the conventional multi-chip prober disclosed in Patent Document 1. FIG. 12(a) is a side view thereof. FIG. 12(b) is a plan view thereof.

As shown in FIG. 12(a), an optical detection unit 101 of a conventional multi-chip prober 100 comprises: an optical power meter 102; a support 103 of the optical power meter 102; an optical power meter moving mechanism 104; an optical fiber 105; a relay unit 106; a support 107; and a fiber moving mechanism 108.

The optical power meter 102 is disposed immediately above a chip to be inspected, for the inspection of the light emitting output of the chip (which is a LED chip herein).

The optical power meter moving mechanism 104 moves the support 103.

A tip of the optical fiber 105 extends close to a chip to be inspected.

The relay unit 106 retains the optical fiber 105, relaying wavelengths of light entering the optical fiber 105 to a monochrometer (not shown) for inspection.

The support 107 supports the relay unit 106.

The fiber moving mechanism 108 moves the support 107.

As shown in FIG. 12(b), the optical detection unit 101 has a shape in which apart for housing the fiber moving mechanism 108 protrudes from a circular part. The optical power meter moving mechanism 104 and the fiber moving mechanism 108 are desirably a moving mechanism using an element, such as a piezo-element, that is capable of operating at a fast speed. It is also possible to use a moving mechanism in which a driving screw and a motor are combined. The optical power meter moving mechanism 104 and the fiber moving mechanism 108 may not be provided if there is no need of moving chips when different chips are inspected.

A needle head 109 has a shape to be disposed around the optical detection unit 101, and comprises a needle unit 109a and seven needle position adjustment mechanisms 109b to 109h.

The needle unit 109a is a unit for securing a reference needle 110a to a needle head 111.

The needle position adjustment mechanism 109e comprises: a needle 110e; a needle retaining unit 112e for retaining the needle 110e; a moving unit 113e to which the needle retaining unit 112e is attached; and a moving mechanism 114e for moving the moving unit 113e. The moving mechanism 114e is capable of moving the needle 110e in two axial directions parallel to a placement surface of a stage 120, e.g., in X-axis and Y-axis directions. The needle position adjustment mechanisms 109b to 109h can be actualized using publicly known moving mechanisms, and the needle position adjustment mechanisms 109b to 109h are desirably moving mechanisms using an element, such as a piezo-element, that is capable of operating at a fast speed. In lieu of this type of moving mechanism, a moving mechanism in which a driving screw and a motor are combined may also be used.

The shifting of the electrode pad position of the chip is small in the direction perpendicular to the placement surface of the stage 120. Moreover, the needle is elastic. The contact will be more accurate as the shifting of the electrode pad position is smaller in this direction. For that reason, the needle position adjustment mechanism does not move the needle in the direction perpendicular to the stage surface. However, when an accurate contacting pressure is required, each needle position adjustment mechanism may be configured to move a corresponding needle in the direction perpendicular to the front surface of the stage 120. As a result, it becomes possible to match the positional relationship of all the needles 110a to 110h with the positional relationship of respective electrode pads of the separated chip 122 adhered on an adhesion tape 121.

FIG. 13 is a diagram of a configuration of an essential part of a conventional wafer test system disclosed in Patent Document 2.

As shown in FIG. 13, a conventional wafer test system 200 is configured with a prober 201 and a tester 202.

The prober 201 comprises: a pedestal 203; a moving base 204 provided on the pedestal 203; a Y-axis moving platform 205; an X-axis moving platform 206; a Z-axis moving part 207; a Z-axis moving platform 208; a θ rotation part 209; a wafer chuck 210; a probe position detecting camera 212 for detecting a position of a probe 211; side plates 213 and 214; a head stage 215; a wafer alignment camera 217 provided for a pillar 216; a card holder 218 provided in the head stage 215; and a controlling part 222 including a stage movement controlling part 219, an image processing part 220 and a temperature controlling part 221. A probe card 223 is attached to the card holder 218. A plurality of probes 211 are provided in the probe card 223.

The moving base 204, Y-axis moving platform 205, X-axis moving platform 206, Z-axis moving part 207, Z-axis moving platform 208 and θ rotation part 209 constitute a movement and rotation mechanism for moving and rotating the wafer chuck 210 in the three axial directions and around the Z-axis. This movement and rotation mechanism is controlled by the stage movement controlling part 219.

The probe card 223 comprises a plurality of probes 211, which are disposed in accordance with the electrode pad disposition of the device for inspection. The probe card 223 is replaced in accordance with the device for inspection.

The image processing part 220 calculates the disposition and height position of the probe 211 based on an image taken by the probe position detecting camera 212. The image processing part 220 also detects a position of an electrode pad of a semiconductor chip (die) on a semiconductor wafer W from an image taken by the wafer alignment camera 217. The image processing part 220 is capable of detecting a contact trace caused by the contact to the electrode pad by the probe 211 by image-processing of a detected image, and is also capable of recognize the position, size and the like of the contact trace in the electrode pad through the image.

A tester 202 comprises a tester body, and a contact ring 224 provided in the tester body. The probe card 223 comprises a terminal provided therein, which is connected to each probe 211. The contact ring 224 comprises a spring probe disposed in such a manner to contact with the terminal of the probe card 223. The tester body is retained to the prober 211 by a supporting mechanism (not shown).

With the configuration described above, as shown in FIG. 14(a), the Z-axis moving platform 208 is first moved in the X and Y directions so that the probe position detecting camera 212 will be positioned below the probe 211, and the probe position detecting camera 212 detects a tip position of the probe 211. The position (X coordinate and Y coordinate) of the tip of the probe 211 in a horizontal plane is detected by the positional coordinates of the probe position detecting camera 212, and the position in the vertical direction (Z coordinate) is detected by the focusing position of the probe position detecting camera 212. The detection of the tip position of the probe 211 is always required whenever the probe cards 223 are replaced. Furthermore, the detection of the tip position of the probe 211 is performed every time a predetermined number of chips have been measured even if the probe cards 223 are not replaced. Usually, a 1000 or more probes 211 are provided for the probe card 223; thus, not all of the tip positions of the probes 211 are detected, but the tip positions of particular probes 211 are detected, usually in consideration of working efficiency.

Next, while a wafer W to be inspected is mounted on the wafer chuck 210, the Z-axis moving platform 208 is moved in the X and Y directions so that the wafer W will be positioned below the wafer alignment camera 217, as shown in FIG. 14(b), to detect the position of each electrode pad of the semiconductor chip on the wafer W.

After the detection of the tip position of the probe 211 and the position of the wafer W as described above, the wafer chuck 210 is rotated by the θ rotation part 209 so that the arrangement direction of the electrode pad of the chip on the wafer W correspond to the arrangement direction of the probe 211. The wafer chuck 210 is moved so that the electrode pad of the chip in the wafer W to be inspected will be positioned below the probe 211. Then, the wafer chuck 210 is lifted to allow a plurality of electrode pads to contact with a plurality of probes 211 respectively.

Furthermore, when a plurality of electrode pads are allowed to contact with a plurality of probes 211, the plurality of electrode pads are lifted, by a predetermined degree, to a position (inspection position) higher than a position (contact starting position) at which the surfaces of the plurality of electrode pads come in contact with the tip parts of the plurality of probes 211. The inspection position, which is added to the contact starting position, is a position with a height at which a displacement amount of a tip part of a probe 211 allows for the bending amount of the probe 211 to be obtained, which allows for a contact pressure to actualize a secure electric contact between the probe 211 and the electrode pad. In practice, the number of the plurality of probes 211 is 1000 or more, for example; and the inspection position is set in such a manner that a secure electric contact will be actualized between all the plurality of probes 211 and the plurality of electrode pads. The bending amount may be within a predetermined range, and thus, the accuracy required for the relative position in the Z-axis direction between the probe 211 and the front surface of the wafer W does not need to be as high as the accuracy required in the X-axis and Y-axis directions.

The tester 202 supplies power and various types of test signals from the terminal which is connected to the probe 211, and the tester 202 confirms normal operation by analyzing signals output to the electrode pad of the chip.
Patent Document 1: Japanese Laid-Open Publication No. 2008-70308
Patent Document 2: Japanese Laid-Open Publication No. 2011-222851

### SUMMARY OF THE INVENTION

The conventional multi-chip prober 100 disclosed in Patent Document 1 tests a plurality of chips after being cut by a predetermined number, such as eight. Thus, for the efficiency of the test, the number of needles must be increased in order to increase the number of contact chips inspected at the same time. In a case where the number of needles is increased, however, it was extremely difficult to increase the number of the needle having positional adjustment mechanisms for respective electrode pads of eight chips in order to increase the test efficiency.

In the conventional wafer test system 200 disclosed in Patent Document 2, the electrode pad positions of the plurality of chips on the semiconductor wafer W prior to being cut are accurately arranged. Thus, a large number of probes 211 secured and disposed using the probe card 223 are allowed to contact with respective electrode pads of a large number of chips to measure various types of electric characteristics. However, it was extremely difficult to position a plurality of non-uniformly arranged chips, after being cut, accurately for the contact between the large number of probes 211 of the probe card 223 and respective electrode pads of the large number of non-uniformly arranged chips after being cut.

The present invention is intended to solve the conventional problems described above. It is an objective of the present invention to provide a multi-chip prober; a contact position correction method thereof; and a computer-readable, readable recording medium on which a control program is stored, the control program describing a processing order for allowing a computer to execute respective steps of the contact position correction method, the multi-chip prober being capable of accurately positioning a large number of probes of a probe card and respective electrode pads of a large number of chips with non-uniform positional accuracy after being cut, and capable of significantly increasing the number of simultaneously contacting chips, thereby increasing the efficiency for the test.

A multi-chip prober according to the present invention is provided for allowing respective electrode pads of a plurality of chips, as inspection subjects, to contact simultaneously with respective tip positions of a plurality of probes, the multi-chip prober including: a moving platform capable of securing the plurality of chips, after being cut from a wafer, on an upper surface thereof, movable in three axial directions, such as X-axis, Y-axis and Z-axis, and rotatable around the Z-axis; a probe position detecting section for detecting the tip position of the plurality of probes; a pad position detecting section for detecting a position of the electrode pads of the plurality of chips; a probe section provided with the plurality of probes, for making contact with the electrode pads; and a position controlling apparatus for detecting respective positions of the plurality of probe tips and the electrode pads based on respective images from the probe position detecting section and the pad position detecting section, and controlling three axial coordinate positions as well as a rotational position around the Z-axis of the electrode pads on the moving platform based on detected respective positions of the plurality of probe tips and the electrode pads, so that the electrode pads of the chips, as inspection subjects, will correspond to the tip positions of the plurality of probes, thereby achieving the objective described above.

Preferably, a multi-chip prober according to the present invention further includes: a probe and pad position detecting section for detecting a position of the electrode pads of the plurality of chips and a tip disposition of the plurality of probes; and a batch angle correcting section for corresponding an arrangement angle of the a plurality of chips to a tip arrangement angle of the plurality of probes.

Still preferably, in a multi-chip prober according to the present invention, the batch angle correcting section calculates a rotation angle around the Z-axis from a difference (θ1=θ1A−θ1B) between an arrangement angle (θ1A) of the plurality of probes and an arrangement angle (θ1B) of the electrode pads of the plurality of chips, and rotates the moving platform around the Z-axis so as to correspond to the arrangement angle (θ1A) of the plurality of probes.

Still preferably, a multi-chip prober according to the present invention further includes an individual angle averaging section for correcting a batch angle correction position using an average value of the arrangement angles of the individual chips as inspection subjects.

Still preferably, a multi-chip prober according to the present invention further includes a horizontal direction position correcting section for using an average value of central coordinates of the plurality of chips as a correction value of an arrangement of the plurality of probes in one direction, calculating a deviation amount between a theoretical value and an actual measurement value of chip spaces in another direction that is perpendicular to the one direction, calculating a deviation amount of probe tip spaces, and using a value obtained by subtracting average values of deviation amounts from respective theoretical values of the chip spaces and the probe tip spaces, as a correction value.

Still preferably, a multi-chip prober according to the present invention further includes a horizontal direction position correcting section for correcting central coordinates of a center chip, or central coordinates in between central chips, among the plurality of chips as the inspection subjects, and for correcting central coordinates of a center probe, or central coordinates in between central probes, among the plurality of probes, in such a manner to correspond the central coordinates in X and Y directions.

Still preferably, a multi-chip prober according to the present invention further includes a contact group dividing section for performing division processing on the electrode pads into at least two contact groups of the electrode pads of one or a plurality of chips that are not able to make simultaneous contact, and electrode pads of one or a plurality of the remaining chips, when at least one of the tips of the plurality of probes is not positioned within the range of the electrode pads of the plurality of chips.

Still preferably, a multi-chip prober according to the present invention further includes a contact group dividing section for performing division processing for positional correction processing of a series of a plurality of contact groups of: electrode pads of one or a plurality of chips that are not able to make simultaneous contact; and electrode pads prior to said electrode pads of one or a plurality of chips and electrode pads after said electrode pads of one or a plurality of chips, when at least one of the tips of the plurality of probes is not positioned within the range of the electrode pads of the plurality of chips.

Still preferably, in a multi-chip prober according to the present invention, a XYθ coordinate correction is performed on the electrode pads of one or a plurality of the chips that are not able to make simultaneous contact, on which the contact group dividing section has performed the division processing, so that the respective tips of one or a plurality of probes corresponding to the electrode pads will correspond to the electrode pads of one or a plurality of the chips that are not able to make simultaneous contact.

Still preferably, in a multi-chip prober according to the present invention, the probe section is a probe card.

Still preferably, a multi-chip prober according to the present invention further includes a tester for inspecting at least any of electric operating characteristics and optical characteristics of the plurality of chips as inspection subjects, via the probe section.

A contact position correction method of a multi-chip prober according to the present invention includes a contact position controlling step of, when electrode pads of a plurality of chips, as inspection subjects, are allowed to make simultaneous contact with tip positions of a plurality of probes, a position controlling apparatus detecting a plurality of probe tip positions of a probe section and each position of the electrode pads of the plurality of chips, as inspection subjects, based on respective images from a probe position detecting section and a pad position detecting section, and controlling three axial coordinate positions as well as a rotational position around the Z-axis of the electrode pads of the plurality of chips on a moving platform, based on detected respective positions of the plurality of probe tip positions and the electrode pads of the plurality of chips, as inspection subjects, so that the electrode pads of the plurality of chips, as inspection subjects, will correspond to the tip positions of the plurality of probes, thereby achieving the objective described above.

Preferably, in a contact position correction method of a multi-chip prober according to the present invention, the contact position controlling step includes: a probe and pad position detecting step of a probe and pad position detecting section detecting the position of the electrode pads of the plurality of chips and a tip disposition of the plurality of probes; and a batch angle correcting step of a batch angle correcting section corresponding an arrangement angle of a plurality of chips, as the inspection subjects, to a tip arrangement angle of the plurality of probes.

Still preferably, in a contact position correction method of a multi-chip prober according to the present invention, the batch angle correcting step calculates a rotation angle around the Z-axis from a difference (θ1=θ1A−θ1B) between an arrangement angle (θ1A) of the plurality of probes and an arrangement angle (θ1B) of the electrode pads of the plurality of chips, and rotates the moving platform around the Z-axis so as to correspond to the arrangement angle (θ1A) of the plurality of probes.

Still preferably, in a contact position correction method of a multi-chip prober according to the present invention, the contact position controlling step comprises an individual angle averaging step of an individual angle averaging section correcting a batch angle correction position using an average value of arrangement angles of the individual chips as inspection subjects.

Still preferably, a contact position correction method of a multi-chip prober according to the present invention further includes a horizontal direction position correcting step of a horizontal direction position correcting section using an average value of central coordinates of the plurality of chips as a correction value of an arrangement of the plurality of probes in one direction, calculating a deviation amount between a theoretical value and an actual measurement value of chip spaces in another direction that is perpendicular to the one direction, calculating a deviation amount between a theoretical value and an actual measurement value of probe tip spaces, and using a value obtained by subtracting average values of deviation amounts from respective theoretical values of the chip spaces and the probe tip spaces, as a correction value.

Still preferably, a contact position correction method of a multi-chip prober according to the present invention further includes a horizontal direction position correcting step of a horizontal direction position correcting section correcting central coordinates of a center chip, or central coordinates in between central chips, among the plurality of chips as the inspection subjects, in X and Y directions so as to be positioned to central coordinates of a center probe, or central coordinates in between central probes, among the plurality of probes.

Still preferably, a contact position correction method of a multi-chip prober according to the present invention further includes a contact group dividing step of a contact group dividing section performing division processing on the electrode pads into at least two contact groups of the electrode pads of one or a plurality of chips that are not able to make simultaneous contact, and electrode pads of one or a plurality of the remaining chips, when at least one of the tips of the plurality of probes is not positioned within the range of the electrode pads of the plurality of chips.

Still preferably, a contact position correction method of a multi-chip prober according to the present invention further includes a contact group dividing step of a contact group dividing section performing division processing for positional correction processing of a series of a plurality of contact groups of: electrode pads of one or a plurality of chips that are not able to make simultaneous contact; and electrode pads prior to said electrode pads of one or a plurality of chips and electrode pads after said electrode pads of one or a plurality of chips, when at least one of the tips of the plurality of probes is not positioned within the range of the electrode pads of the plurality of chips.

Still preferably, a contact position correction method of a multi-chip prober according to the present invention further includes a correcting step of performing a XYθ coordinate correction on the electrode pads of one or a plurality of the chips that are not able to make simultaneous contact, on which the contact group dividing section has performed the division processing, so that the respective tips of one or a plurality of probes corresponding to the electrode pads will correspond to the electrode pads of one or a plurality of the chips that are not able to make simultaneous contact.

Still preferably, in a contact position correction method of a multi-chip prober according to the present invention, the probe section is a probe card.

A control program according to the present invention describes a processing order for allowing a computer to execute respective steps of the contact position correction method of a multi-chip prober according to the present invention, thereby achieving the objective described above.

A computer-readable, readable recording medium on which the control program according to the present invention is stored, thereby achieving the objective described above.

The functions of the present invention having the structures described above will be described hereinafter.

According to the present invention, a multi-chip prober for allowing respective electrode pads of a plurality of chips, as inspection subjects, to contact simultaneously with respective tip positions of a plurality of probes, comprises: a moving platform capable of securing a plurality of chips of a wafer after being cut on an upper surface thereof, movable in three axial directions, such as X-axis, Y-axis and Z-axis, and rotatable around the Z-axis; a probe position detecting section for detecting a tip position of a plurality of probes for inspection; a pad position detecting section for detecting a position of electrode pads at the plurality of chips after being cut, as inspection subjects; a probe section provided with a plurality of probes for making contact with the electrode pads; and a position controlling apparatus for detecting respective positions of the plurality of probe tips and the electrode pads based on respective images from the probe position detecting section and the pad position detecting section, and controlling three axial coordinate positions as well as a rotational position of the electrode pads on the moving platform based on detected respective positions of the plurality of probe tips and the electrode pads, so that the electrode pads of the chips, as inspection subjects, will correspond to the tip positions of the plurality of probes.

Accordingly, three axial coordinate positions and the rotational position of electrode pads of chips to be inspected on a moving platform are controlled in such a manner that the electrode pads will correspond to the tip position of a plurality of probes. As a result, a large number of probes of a probe card, and electrode pads of a large number of chips, whose positional accuracy after being cut is uneven, can be positioned with accuracy, thus, largely increasing the number of chips for simultaneous contact, and thus increasing the efficiency for the test.

According to the present invention with the configuration described above, since three axial coordinate positions and the rotational position of electrode pads of chips to be inspected on a moving platform are controlled in such a manner that the electrode pads will correspond to the tip position of a plurality of probes, a large number of probes of a probe card, and electrode pads of a large number of chips, whose positional accuracy after being cut is uneven, can be positioned with accuracy, thus largely increasing the number of chips for simultaneous contact, and thus increasing the efficiency for the test.

These and other advantages of the present invention will become apparent to those skilled in the art upon reading and understanding the following detailed description with reference to the accompanying figures.

### BRIEF DESCRIPTION OF THE DRAWINGS

FIG. 1 is a configuration diagram of an essential part, showing an exemplary diagrammatic configuration of a multi-chip prober according to Embodiment 1 of the present invention.

FIG. 2 is a schematic view showing an aspect of inspection with simultaneous contact with a large number of electrode pads, using the multi-chip prober of FIG. 1.

FIGS. 3(a) and 3(b) each are a partial plan view showing an irregular arrangement state of chips after being cut from a semiconductor wafer.

FIG. 4 is a block diagram showing an exemplary diagrammatic configuration of a position controlling apparatus of a multi-chip prober in FIG. 1.

FIG. 5 is a flowchart for describing an operation of a position controlling apparatus of a multi-chip prober in FIG. 1.

FIG. 6 is a diagram for describing batch angle correction processing at Step S3 in FIG. 5.

FIG. 7 is a diagram for describing individual angle correction processing at Step S4 in FIG. 5.

FIG. 8 is a diagram for describing horizontal direction correction processing (part 1) at Step S5 in FIG. 5.

FIG. 9 is a diagram for describing horizontal direction correction processing (part 2) at Step S5 in FIG. 5.

FIG. 10 is a diagram for describing contact group divisional correction processing at Step S11 in FIG. 5.

FIG. 11 is a plan view of a chip of a conventional case of only a θ correction to a wafer, and a chip of a case of Embodiment 1, where a batch θ correction and an individual θ correction at chip arrangement units as well as a horizontal direction position adjustment are performed.

FIG. 12 is a diagram showing an exemplary configuration of a needle head and an optical detection unit part of a conventional multi-chip prober disclosed in Patent Document 1. FIG. 12(a) is a side view thereof. FIG. 12(b) is a plan view thereof.

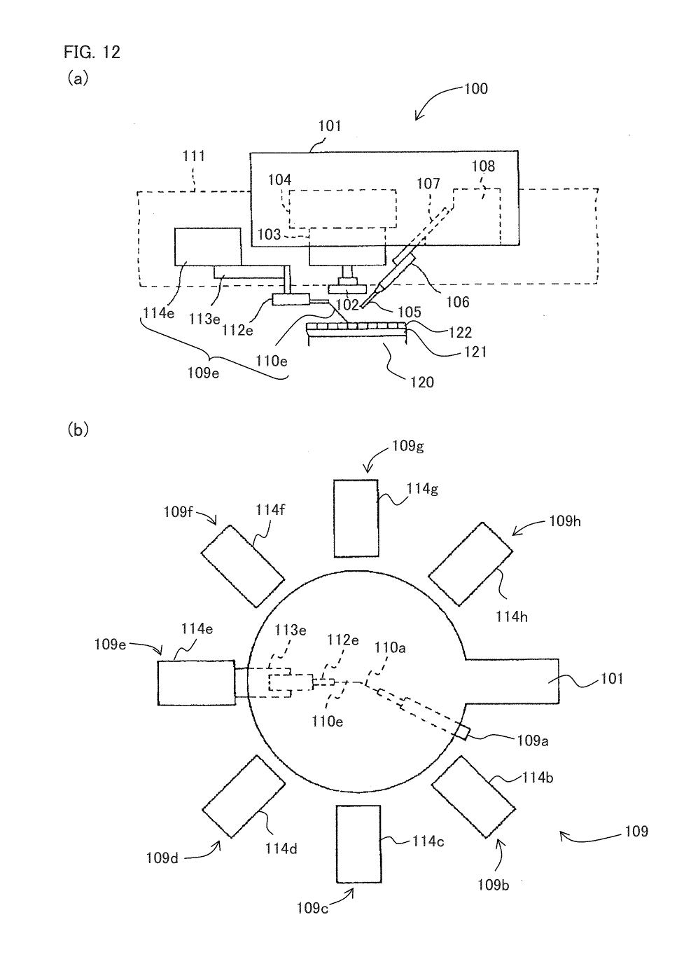

FIG. 13 is a diagram of a configuration of an essential part of a conventional wafer test system disclosed in Patent Document 2.

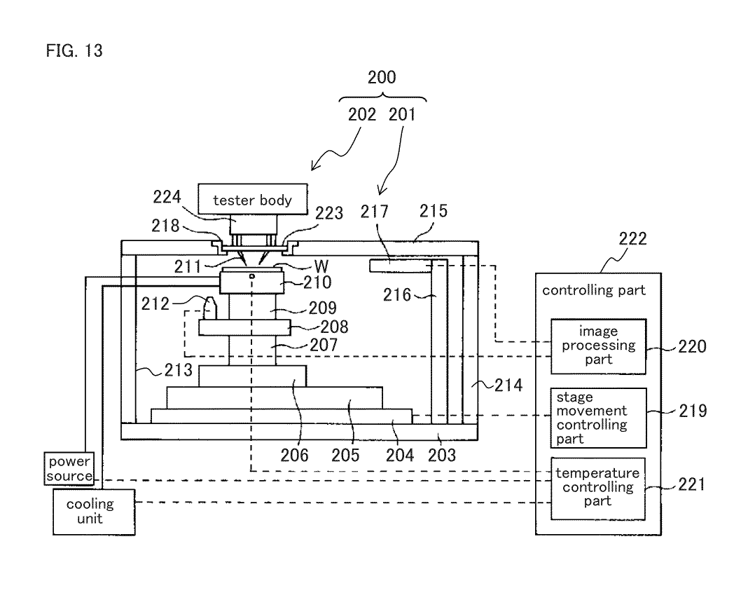

FIG. 14(a) and (b) are both configuration diagrams of an essential part of a conventional wafer test system disclosed in Patent Document 2.

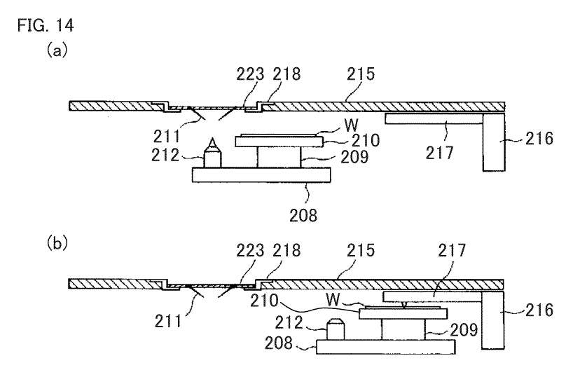

1 multi-chip prober
2 prober
21 chips
22 pedestal
23 moving platform
24 probe
25 top side
26 probe card
27 position controlling apparatus
271 operational input part
272 display part
273 CPU (controlling part)
273A probe and pad position detecting section
273B batch angle correcting section
273C individual angle averaging section
273D horizontal direction position correcting section
273E inspection operation section
273F contact group dividing section
274 RAM
275 ROM
3 tester
31 operating characteristic tester
32 integrating sphere
33 optical characteristic tester
28 adhesion tape

### DESCRIPTION OF THE PREFERRED EMBODIMENTS

Hereinafter, Embodiment 1 of the present invention will be described in detail with regard to a multi-chip prober according to the present invention; a contact position correction method thereof; a control program describing a processing order for allowing a computer to execute respective steps of the contact position correction method; and a contact position correction method thereof; and a computer-readable, readable recording medium on which the control program is stored, with reference to the accompanying figures. Note that the thicknesses, lengths and the like of constituent elements in each of the figures are not limited to those of the illustrated structures in terms of the provided figures.

### Embodiment 1

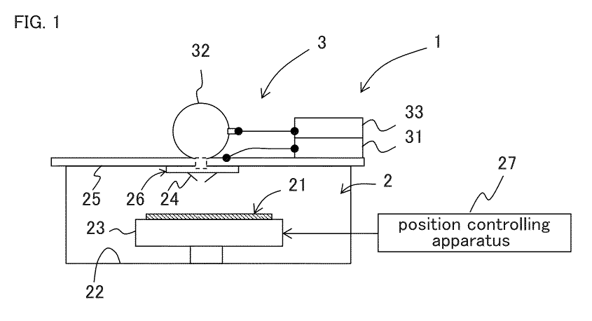

FIG. 1 is a configuration diagram of an essential part, showing an exemplary diagrammatic configuration of a multi-chip prober according to Embodiment 1 of the present invention.

In FIG. 1, a multi-chip prober 1 is constituted of a prober 2 and a tester 3.

The prober 2 comprises: a moving platform 23 capable of securing chips 21 after being cut on an upper surface thereof, movable in three axial directions, such as X-axis, Y-axis and Z-axis, provided on a pedestal 22, and rotatable around the Z-axis; a probe position detecting camera (not shown) functioning as a probe position detecting section for detecting a tip position of a probe 24; a pad position detecting camera (not shown) functioning as a pad position detecting section for detecting a position of an electrode pad of each of the chips 21 after being cut; a probe card 26 disposed on a top side 25, functioning as a probe section provided with a large number of probes 24 for making contact with electrode pads; and a position controlling apparatus 27 for controlling three axial coordinate position of coordinates (X, Y and Z) of the moving platform 23. The probe position detecting camera (not shown) may be provided on the outer circumference side of the moving platform 23, and the probe position detecting camera may also be provided at any other position as long as it can detect a tip position of the probe 24. Furthermore, the pad position detecting camera (not shown) may be provided on the top side 25, and the pad position detecting camera may be provided at any other position as long as it can detect a position of the electrode pad of each of the chips 21 after being cut.

The probe card 26 comprises a large number of probes 24 disposed in accordance with the disposition of a device to be inspected, such as an electrode pad of an LED element. The probe card 26 is replaceable in accordance with a device to be inspected (or LED chip herein). The probe card 26 usually includes a large number of probes 24 (100 or more, or 1000 or more) provided therefor. However, the number of the large number of probes 24 may be, for example, ten. Herein, the explanation is provided with regard to four, or eight, pairs of probes 24 for simplification of the explanation.

The position controlling apparatus 27 detects positions of probes 24 and electrode pads based on images from the probe position detecting camera and the pad position detecting camera. Furthermore, the position controlling apparatus 27 controls three axial coordinate (X, Y and Z) positions of each electrode pad on the moving platform 23 so that the electrode pad of each chip to be inspected corresponds to a tip position of each probe, and also controls a rotational position (θ), based on respective positions of each probe and each electrode pad which are detected. Specifically, the position controlling apparatus 27 calculates a tip disposition and a height position of a probe 24 from an image taken by the probe position detecting camera, and detects a position of an electrode pad of each chip based on an image taken by the pad position detecting camera. The position controlling apparatus 27 further performs operation processing so that tips of a plurality of probes 24 will come in contact and make contact with respective electrode pads of a group of a plurality of chips to be inspected, based on respective positions of respective probes and respective electrode pads, and the position controlling apparatus 27 will move and control the moving platform 23 together with a plurality of chips on the moving platform 23.

The tester 3 comprises an operating characteristic tester 31 for inspecting electric operating characteristics, such as IV characteristics, of a device to be inspected, e.g., an LED chip; and an optical characteristic tester 33 for inspecting optical characteristics, such as luminescent color and luminescent amount, by allowing light emitted from an LED chip to enter an integrating sphere 32 from a center window of the probe card 26. The probe card 26 is provided with terminals connected to respective probes 24. The terminals are connected to the operating characteristic tester 31. The operating characteristic tester 31 performs predetermined inspection by applying a predetermined voltage to, or sending a predetermined electric current through, electrode pads of respective chips 21, from respective terminals via probes 24.

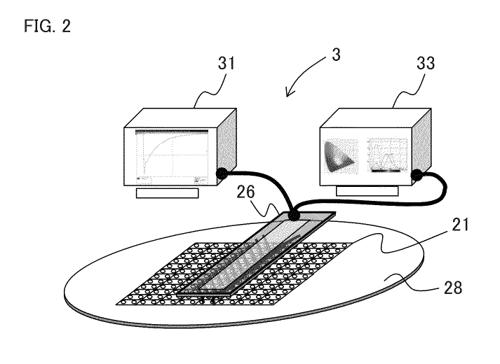

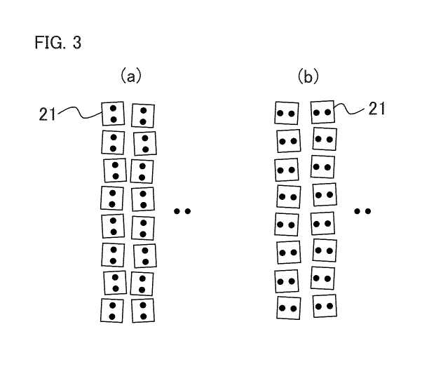

FIG. 2 is a schematic view showing an aspect of inspection with simultaneous contact with a large number of electrode pads, using the multi-chip prober of FIG. 1. FIGS. 3(a) and 3(b) each are a partial plan view showing an irregular arrangement state of chips 21 after being cut from a semiconductor wafer.

As shown in FIGS. 2, 3(a) and 3(b), a large number of chips 21 after being cut are attached on a stretchable adhesion tape 28, which is attached on a back surface of a plate-shaped frame with holes. The disposition of electric pads of a large number of chips 21 after being cut from a semiconductor wafer may be such an arrangement as in a longitudinal direction in FIG. 3(a) or may be such an arrangement as in a transverse direction in FIG. 3(b). In any case, with regard to the positions of chips 21, since the adhesion tape 28 is stretched and the space in between the chips 21 is widened, the space between the chips 21 varies and thus the chips are arranged in an irregular manner. For the disposition of the electrode pads of the large number of chips 21 that, after being cut, are arranged irregularly, the respective probes 24 secured to the probe card 26 are allowed to make maximum contact by the position controlling apparatus 27 moving and controlling three axial positions and a rotational position of the moving platform 23. The controlling of the three axial positions and rotational position of the moving platform 23 by the position controlling apparatus 27 will be described in detail.

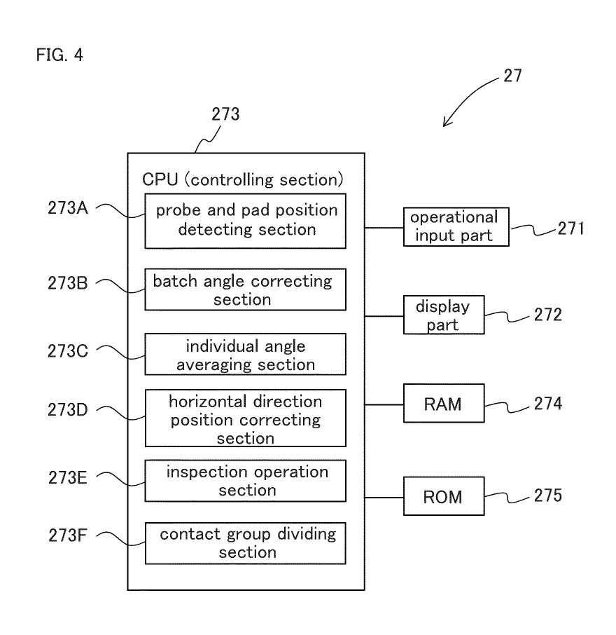

FIG. 4 is a block diagram showing an exemplary diagrammatic configuration of a position controlling apparatus 27 of a multi-chip prober 1 in FIG. 1.

In FIG. 4, the position controlling apparatus 27 according to Embodiment 1 is configured with a computer system. The position controlling apparatus 27 comprises: an operational input part 271, such as a keyboard, mouse and a screen input device, capable of inputting various commands; a display part 272 capable of displaying various images, such as an initial screen, a selection guiding screen, and a processing result screen, on a display screen in accordance with various input commands; a CPU 273 (central processing unit) functioning as a controlling section for performing overall controlling; a RAM 274 functioning as a temporary storage section that works as a work memory when the CPU 273 is started up; and a ROM 275 functioning as a computer-readable, readable recording medium (storage section), on which a control program for operating the CPU 273 and various data used therefor are stored.

The CPU 273 (controlling section) comprises: a probe and pad position detecting section 273A for detecting a position of each electrode pad of each chip 21 and a tip disposition of each probe 24, based on input commands from the operational input part 271, as well as control programs read from the ROM 275 to the RAM 274 and various data used therefor; a batch angle correcting section 273B for corresponding the angle (tilting) of all the chips 21 to the tip disposition of the probe 24; an individual angle averaging section 273C for correcting a batch angle correction position using an average value of a tilt angle of each of the chips 21; a horizontal direction position correcting section 273D for correcting X and Y coordinates so that chip spaces and probe tip spaces will correspond with one another using a correction value obtained by calculating a difference between an average value of probe tip spaces and chip spaces; an inspection operation section 273E for performing operations, such as a matching operation between respective tip positions of a plurality of probes 24 and positions of electrode pads of a plurality of chips 21, a contact operation, and a moving operation to a next inspection subject; and a contact group dividing section 273F for performing division processing for a series of contact groups of at least each electrode pad of one or a plurality of chips 21 that are not able to make simultaneous contact, and each electrode pad of one or a plurality of the other chips 21.

The probe and pad position detecting section 273A detects a position of each electrode pad of each chip 21 and a tip disposition of each probe 24 based on images from the probe position detecting camera and the pad position detecting camera.

The batch angle correcting section 273B calculates an optimum wafer rotation angle from a difference (θ1=θ1A−θ1B) between a tilt of a probe disposition (θ1A) and a tilt of an electrode pad disposition (θ1B), and rotates the moving platform 23 (wafer stage) around the Z-axis to an optimum position with respect to the disposition of each probe 24. As a result, the angle of the overall wafer (all the chips) corresponds to a needle tip angle (tip disposition of the probe 24).

The individual angle averaging section 273C further corrects the batch angle correction position by the batch angle correcting section 273B based on an average value calculated from tilt angles (θ2A, θ2B, θ2C and θ2D) of respective chips 21.

The horizontal direction position correcting section 273D uses an average value of the chip central coordinates as a reference for needle contacting of probes 24 in one direction. The horizontal direction position correcting section 273D calculates a deviation amount from a theoretical value and an actual measurement value of a chip space in another direction. The horizontal direction position correcting section 273D calculates a deviation amount from a theoretical value and an actual measurement value of the needle tip space. The horizontal direction position correcting section 273D then subtracts a deviation average value from a theoretical value of a chip space and a needle tip space (probe tip space), and uses the deviation average value as a correction value. Specifically, the horizontal direction position correcting section 273D: uses an average value of the central coordinates of each chip 21 as a correction value in an arrangement of respective probes in one direction; calculates a deviation amount between a theoretical value and an actual measurement value of chip spaces in another direction; calculates a deviation amount between a theoretical value and an actual measurement value of each probe tip space; and uses a value obtained by subtracting an average value of a deviation amount from each theoretical value of each chip space and each probe tip space, as a correction value.

Alternatively, the horizontal direction position correcting section 273D corrects central coordinates of the center chip or central coordinates in between central chips for simultaneous measurement (that are measured simultaneously) among a plurality of chips 21 as correction subjects, and corrects central coordinates of the central probe 24 or between central probes 24 among a plurality of probes 24, in such a manner to position them in the X and Y directions.

The inspection operation section 273E detects whether or not each of the tips of a plurality of probes 24 are positioned within the range of all the electrode pads of a plurality of chips 21. The inspection operation section 273E also lifts the moving platform 23 together with a plurality of chips 21 in the Z-axis direction to control respective electrode pads of the plurality of chips 21 as inspection subjects, allowing them to contact with a plurality of probes 24 of a probe card 26. The inspection operation section 273E determines whether or not all of the inspection has been completed for respective electrode pads of a plurality of chips 21 cut from a semiconductor wafer. If the inspection operation section 273E determines that not all of the inspection has been completed for respective electrode pads of a plurality of chips 21, then the inspection operation section 273E moves the moving platform 23 together with the plurality of chips 21 so that the next chip group to be inspected will correspond to the position of the probe card 26. The inspection operation section 273E further detects whether or not the tips of one or a plurality of probes 24 corresponding to one divided group are positioned within the range of all the electrode pads of one or a plurality of chips 21 of one divided group. Furthermore, the inspection operation section 273E determines whether or not all of the inspection for each electrode pad of one or a plurality of chips 21 of one divided group have been completed.

The contact group dividing section 273F performs division processing for positional correction processing of a series of three contact groups of: a first group of electrode pads of one or a plurality of chips 21 that are not able to make simultaneous contact; and groups prior to and after the first group, the prior and after groups each including respective electrode pads of one or a plurality of chips 21. Alternatively, the contact group dividing section 273F performs division processing for positional correction processing of a series of two contact groups of: a first group of electrode pads of one or a plurality of chips 21 that are not able to make simultaneous contact; and the other group of electrode pads of remaining one or a plurality of chips 21.

The ROM 6 is constituted of a readable storage medium (recoding section), such as a hard disk, an optical disk, a magnetic disk or an IC memory. The control program and various data used therefor may be downloaded to the ROM 275 from a portable optical disk, magnetic disk or IC memory, or may be downloaded to the ROM 275 from a hard disk of a computer, or may be downloaded to the ROM 275 via radio, wire or the Internet and the like.

The operation of the configuration described above will be described hereinafter.

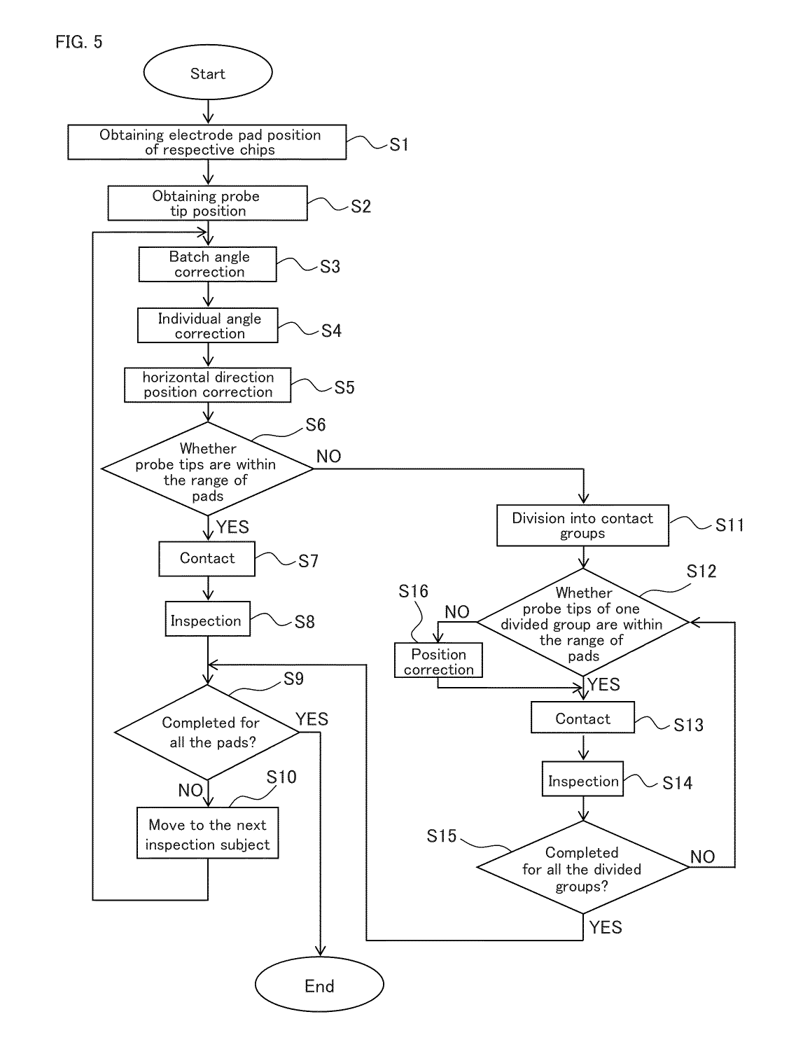

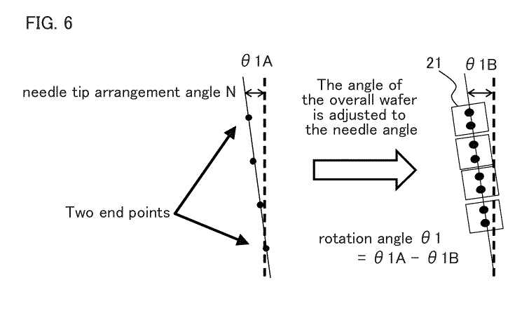

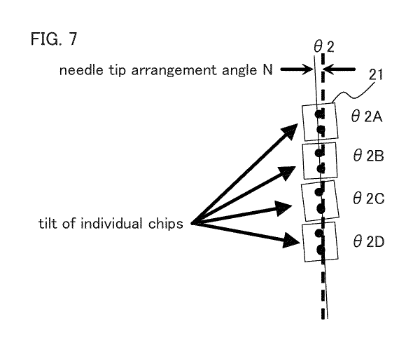

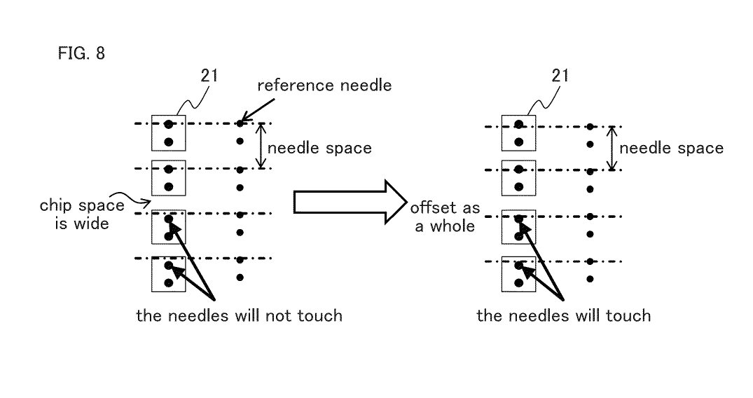

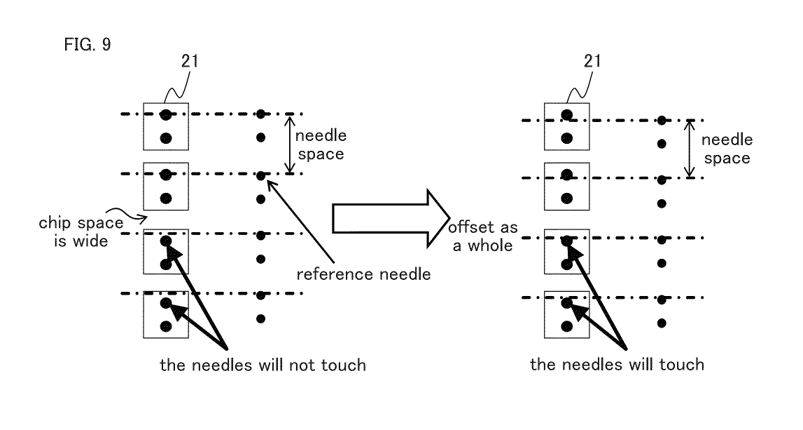

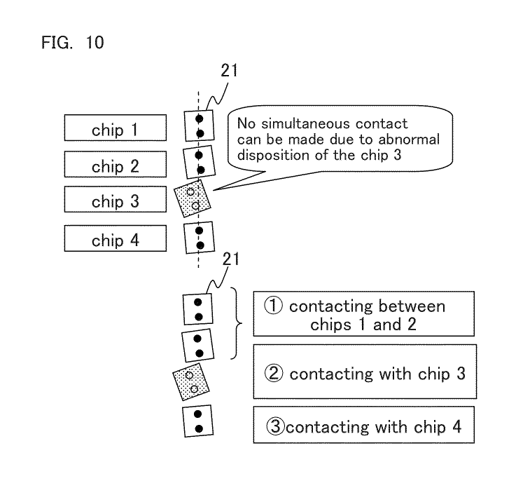

FIG. 5 is a flowchart for describing an operation of a position controlling apparatus 27 of a multi-chip prober 1 in FIG. 1. FIG. 6 is a diagram for describing batch angle correction processing at Step S3 in FIG. 5. FIG. 7 is a diagram for describing individual angle correction processing at Step S4 in FIG. 5. FIGS. 8 and 9 are each a diagram for describing horizontal direction correction processing (part 1 and part 2) at Step S5 in FIG. 5. FIG. 10 is a diagram for describing contact group divisional correction processing at Step S11 in FIG. 5.

As shown in FIG. 5, first, in the electrode pad disposition obtaining processing at Step S1, the moving platform 23 and a large number of chips 21 thereon are moved to a position below the pad position detecting camera. The pad position detecting camera takes an image of the electrode pads of the large number of chips 21, and the probe and pad position detecting section 273A detects the position of the electrode pads of the chips 21 based on the image of the electrode pads taken.

Next, in the tip disposition obtaining processing of probes 24 at Step S2, the probe position detecting camera is moved together with the moving platform 23 right below the tip disposition of the probe 24, and the image of the tip disposition of the probe 24 is taken by the probe position detecting camera. The probe and pad position detecting section 273A detects the tip disposition of the probe 24 based on the image of the tip disposition of the probe 24 taken.

Then, in the batch angle correction processing at Step S3, the batch angle correcting section 273B calculates an optimum wafer rotation angle from a difference (θ1=θ1A−θ1B) between a tilt of a probe disposition (θ1A) and a tilt of an electrode pad disposition (θ1B) as shown in FIG. 6, and rotates the moving platform 23 (wafer stage) around the Z-axis to an optimum position with respect to the disposition of each probe 24. Accordingly, the angle of the overall wafer (all the chips) corresponds to a needle tip angle (tip disposition of the probe 24). Specifically, the batch angle correcting section 273B controls three axial coordinate (X, Y and Z) positions as well as a rotational position (θ) of the moving platform 23 in such a manner that the tilt of the row of electrode pads of a plurality of chips 21 to be inspected will correspond to the tilt of the line connecting both ends of the row of the tip disposition of the probes 24.

Then, in the individual angle correction processing at Step S4, the individual angle averaging section 273C detects tilt angles (θ2A, θ2B, θ2C and θ2D) of each of chips 21 from an image, as shown in FIG. 7, and calculates an average value thereof from the tilt angles (θ2A, θ2B, θ2C and θ2D) of each of chips 21 detected. Xyθ coordinate is then calculated using the average value as a θ correction value θ2. With regard to the correction position calculated at Step S3, the average value, i.e., θ correction value θ2, is calculated from the tilt of all the chips 21 as the subject of needle contacting (as the inspection subject), and XYθ coordinates of respective chips 21 are corrected based on the θ correction value θ2.

θ correction value θ2=(θ2A+θ2B,θ2C+θ2D)/4

Furthermore, in the horizontal direction (surface directions in the X direction and Y direction) position correction processing at Step S5, the horizontal direction position correcting section 273D uses an average value of tip coordinates in the X direction as a needle contact reference for probes 24 when a plurality of chips 21 to be inspected are arranged in a longitudinal direction (Y direction) as shown in FIG. 8. A deviation amount is calculated from a theoretical value and an actual measurement value of a chip space in the Y direction. A deviation amount is calculated from a theoretical value and an actual measurement value of a needle tip space. A deviation average value from a theoretical value of a chip space and a needle tip space is subtracted, and a thus obtained value is used as a correction value. That is, an average value of a chip space and a needle tip space is calculated as a correction value, and the X and Y coordinates are corrected such that the chip space will correspond to the probe tip space.

In addition, when a plurality of chips 21 to be inspected are arranged transversely (in the X direction), the average value of chip coordinates is used as a needle contact reference of probes 24 in the Y direction. A deviation amount is calculated from a theoretical value and an actual measurement value of a chip space in the X direction. A deviation amount is calculated from a theoretical value and an actual measurement value of a needle tip space. A deviation average value from a theoretical value of a chip space and a needle tip space is subtracted, and a thus obtained value is used as a correction value. That is, an average value of a chip space and a needle tip space is calculated as a correction value, and the X and Y coordinates are corrected such that the chip space will correspond to the probe tip space.

Alternatively, in the horizontal direction position correction processing at Step S5, the horizontal direction position correcting section 273D positions the central coordinates of the center chip or the central coordinates in between central chips for simultaneously measurement among a plurality of chips 21 as correction subjects, and positions the central coordinates of the central probe 24 or between central probes 24 among a plurality of probes 24, in the X and Y directions, as shown in FIG. 9.

Next, at Step S6, whether or not all the tips of a plurality of probes 24 are positioned within the range of all the electrode pads of a plurality of chips 21 to be inspected is determined.

That is, if the inspection operation section 273E determines that all the tips of a plurality of probes 24 are positioned within the range of all the electrode pads of a plurality of chips 21 at Step S6 (YES), then the inspection operation section 273E of the position controlling apparatus 27 will lift the moving platform 23 together with a plurality of chips 21 in the Z-axis direction and allows the inspection subject, i.e., respective electrode pads of the plurality of chips 21, to contact with the plurality of probes 24 of the probe card 26, in the contact processing at Step S7.

As a result, in the inspection processing at Step S8, a predetermined voltage is applied successively to a pair of electrode pads of a plurality of chips 21 via a pair of probes 24 of the probe card 26, thus successively inspecting VI characteristics and optical characteristics.

Furthermore, at Step S9, the inspection operation section 273E of the position controlling apparatus 27 determines whether or not all of the inspection has been completed for the respective electrode pads of the plurality of chips 21. At Step S9, if the inspection operation section 273E of the position controlling apparatus 27 determines that all of the inspection has been completed for the respective electrode pads of the plurality of chips 21 (YES), then all the processing will be completed. Alternatively, at Step S9, if the inspection operation section 273E of the position controlling apparatus 27 determines that not all of the inspection has been completed for the respective electrode pads of the plurality of chips 21 (NO), then the inspection operation section 273E will move the moving platform 23 together with the plurality of chips 21 at Step S10 so that the next chip group for inspection will come right below the plurality of probes 24 of the probe card 26. Then, the flow will go back to the batch angle correction processing at Step S3. At this stage, the flow may go back to the electrode pad disposition obtaining processing at Step S1 to repeat the processing successively.

On the other hand, if the inspection operation section 273E determines that at least one of the tips of the plurality of probes 24 is not positioned within the range of the electrode pads of the plurality of chips 21 (NO), then in the contact group division processing at step S11, if the electrode pad of the third chip 21 from the top is not able to make simultaneous contact, assuming that there are four chips 21 to be inspected as shown in FIG. 10, then division processing will be performed on the contact groups such that the contact groups will be divided into three, such as the group of the first and second chips 21 from the top, the third chip 21 from the top, and the fourth chip 21 from the top. Alternatively, if the electrode pad of the third chip 21 from the top is not able to make simultaneous contact, assuming that there are four chips 21 to be inspected, then division processing may be performed on the contact groups such that the contact groups will be divided into two, such as the group of the first, second and fourth chips 21 from the top, and the group of the remaining, third chip 21 from the top that is not able to make simultaneous contact. In summary, the contact group dividing section 273F performs division processing for positional correction processing of a series of three contact groups of a first group of electrode pads of the chip 21 that are not able to make simultaneous contact; and groups prior to and after the first group, the prior and after groups each including electrode pads of respective chips 21. Alternatively, the contact group dividing section 273F performs division processing for positional correction processing of a series of two contact groups of: a first group of electrode pads of the chip 21 that are not able to make simultaneous contact; and the other group of electrode pads of the remaining one or plurality of chips 21.

Next, at Step S12, the inspection operation section 273E detects whether or not the tips of one or a plurality of probes 24 corresponding to one divided group are positioned within the range of all the electrode pads of one or a plurality of chips 21 of one divided group.

At Step S12, if the tips of one or a plurality of corresponding probes 24 are positioned within range of all the electrode pads of one or a plurality of chips 21 of one divided group (YES), then in the contact processing at Step S13, the inspection operation section 273E of the position controlling apparatus 27 lifts the moving platform 23 together with the plurality of chips 21 in the Z axis direction to allow respective electrode pads of the plurality of chips 21, as divisional inspection subjects, to contact with the plurality of probes 24 of the probe card 26.

As a result, in the inspection processing at Step S14, predetermined voltage is applied successively to a pair of electrode pads of one or a plurality of chips 21 successively via a pair of probes 24 of the probe card 26, thus successively inspecting VI characteristics and optical characteristics.

Furthermore, at Step S15, the inspection operation section 273E of the position controlling apparatus 27 determines whether or not all of the inspection has been completed for respective electrode pads of one or a plurality of chips 21 of divided groups. At Step S15, if the inspection operation section 273E of the position controlling apparatus 27 determines that all of the inspection has been completed for respective electrode pads of one or a plurality of chips 21 of respective divided groups (YES), then the flow goes to the processing at Step S9.

At Step S15, if the inspection operation section 273E of the position controlling apparatus 27 determines that not all of the inspection has been completed for respective electrode pads of one or a plurality of chips 21 of respective divided groups (NO), then the flow goes to the processing at Step S12, and the inspection operation section 273E detects whether or not the tips of one or a plurality of probes 24 corresponding to the next one divided group are positioned within the range of all the electrode pads of one or a plurality of chips 21 of one divided group, which is the next inspection subjects. At step S12, if the tips of one or a plurality of corresponding probes 24 are not positioned within the range of all the electrode pads of one or a plurality of chips 21 of the next one divided group (NO), then position correction processing is performed by corresponding the central coordinates the chips 21 that are not able to make simultaneous contact to the central coordinates of a pair of probes 24 of the corresponding probe card 26 at Step S16. Then, the flow goes to the contact processing at Step S13. The above-mentioned processing will be repeated until the inspection processing has been completed for the electrode pads of all the chips 21. Note that the address of the chips 21 that are not able to make simultaneous contact may be stored on a storage section without performing the processing at Step S16, and then the flow may be go to the processing at Step S15.

In summary, the contact position correction method of the multi-chip prober 1 according to Embodiment 1 comprises: a probe and pad position detecting step of detecting a position of each electrode pad of each of a plurality of chips 21 and a tip disposition of a plurality of probes 24 by a probe and pad position detecting section 272A; a batch angle correcting step of corresponding an arrangement angle of a plurality of chips 21 to be inspected to a tip arrangement angle of a plurality of probes 24 by a batch angle correcting section 273B; an individual angle averaging step of correcting a batch angle correcting position using an average value of arrangement angles of individual chips by an individual angle averaging section 273C; a horizontal direction position correcting step of using an average value of central coordinates of the plurality of chips 21 as a correction value of an arrangement of a plurality of probes 24 in one direction, calculating a deviation amount between a theoretical value and an actual measurement value of each chip space in another direction, calculating a deviation amount between a theoretical value and an actual measurement value of each probe tip space, and using a value, as a correction value, obtained by subtracting each average value of deviation amounts from respective theoretical values of respective chip spaces and respective probe tip spaces by a horizontal direction position correcting section 273D; or a horizontal direction position correcting step of correcting central coordinates of the center chip or central coordinates in between central chips among a plurality of chips 21 as correction subjects to position in the X and Y direction to the central coordinates of tip coordinates of the center probe or central coordinates in between central probes among a plurality of probes 24 by the horizontal direction position correcting section 273D; a contact group dividing step of performing division processing into a plurality of contact groups of at least electrode pads of one or a plurality of chips 21 that are not able to make simultaneous contact, and electrode pads of one or a plurality of remaining chips 21, by the contact group dividing section 273F if at least one of the tips of the plurality of probes 24 is not positioned within the range of the electrode pads of the plurality of chips 21 to be inspected; or a contact group dividing step of performing division processing for positional correction processing of a series of a plurality of contact groups of a first group of electrode pads of one or a plurality of chips 21 that are not able to make simultaneous contact, and groups prior to and after the first group, the prior and after groups each including respective electrode pads of one or a plurality of chips 21 by the contact group dividing section 273F; and a correcting step of making a XYθ coordinate correction for a position of each electrode pad of one or a plurality of chips 21, on which division processing has been performed, and which are not able to make simultaneous contact, by the contact group dividing section 273F, so that the tip position of one or a plurality of probes 24 will correspond to each electrode pad of one or a plurality of the chips 21.

As described above, Embodiment 1 comprises a probe and pad position detecting step; a batch angle correcting step; an individual angle averaging step; a horizontal direction position correcting step; a contact group dividing step; and a correcting step of making the XYθ coordinate correction. However, at least any of the individual angle averaging step, horizontal direction position correcting step, contact group dividing step, or correcting step of making the XYθ coordinate correction may not be comprised. However, if the contact group dividing step is not comprised, then the correcting step of making the XYθ coordinate correction will also not be comprised.

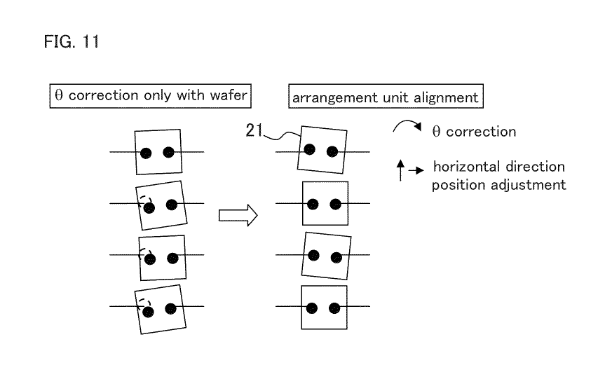

Thus, as shown in FIG. 11, while only a θ correction for pads has been conventionally made with respect to each probe (where the pitch is shown with a dotted line) of a probe card 26 at semiconductor wafer units, a batch θ correction as well as an individual θ correction are performed with respect to probes of a probe card 26 to be corrected at chip arrangement units. Moreover, a chip position adjustment in a horizontal direction (X, Y) is also performed with respect to probes of the probe card 26 to be corrected at chip arrangement units. Thus, simultaneous contact of a certainly larger number of probes 24 can be actualized with a large number of chips 21 after being cut.

According to Embodiment 1 as described above, a multi-chip prober 1 for allowing respective electrode pads of a plurality of chips 21, as inspection subjects, to contact simultaneously with respective tip positions of a plurality of probes 24, comprises: a moving platform 23 capable of securing a plurality of chips 21 of a wafer after being cut on an upper surface thereof, movable in three axial directions, such as X-axis, Y-axis and Z-axis, and rotatable around the Z-axis; a probe position detecting camera for detecting a tip position of a plurality of probes 24 for inspection; a pad position detecting camera for detecting a position of electrode pads at the plurality of chips 21 after being cut, as inspection subjects; a probe card 26, as a probe section, provided with a plurality of probes 24 for making contact with the electrode pads; and a position controlling apparatus 27 for detecting respective positions of the plurality of probe tips and the electrode pads based on respective images from the probe position detecting camera and the pad position detecting camera, and controlling three axial coordinate positions as well as a rotational position of the electrode pads on the moving platform 23 based on detected respective positions of the plurality of probe tips and the electrode pads, so that the electrode pads of the chips 21, as inspection subjects, will correspond to the tip positions of the plurality of probes 24.

As described above, the probe card 26 is used for simultaneous contact with electrode pads of a large number of chips 21. The positions of electrode pads of a plurality of chips 21 for contacting and the tip positions of probes 24 of a probe card 26 are recognized, and X-axis, Y-axis and θ adjustments can be performed at maximum accuracy to the tip positions of probe 24 of a probe card 26 in an optimum manner with respect to electrode pads of chips 21. If there are chips 21 that are not physically able to make contact, the chips 21 will be divided into small units, such as one or a plurality of chip groups that are able to make contact. Individual positional correction is performed on the chips 21 that are not physically able to make contact, thus, preventing poor contact.

As a result, it becomes possible to position a large number of probes of a probe card and electrode pads of a large number of chips accurately, thus increasing the number of chips that make simultaneous contact, and thus increasing the efficiency for the test. Accordingly, the efficient simultaneous contact of a plurality of chips 21 allows inspection time for semiconductor wafers to be reduced. Accordingly, a cut in the cost for inspection and a reduction of the number of inspection devices necessary can be actualized.

In Embodiment 1, a case has been described where the afore-mentioned probe and pad position detecting section 273A, batch angle correcting section 273B, individual angle averaging section 273C, horizontal direction position correcting section 273D, contact group dividing section 273F, and correction section (not shown) for correcting the XYθ coordinates are comprised; however, without the limiting to these, at least any of the individual angle averaging section 273C, horizontal direction position correcting section 273D, contact group dividing section 273F, and correction section (not shown) for correcting the XYθ coordinates may not be comprised. However, if the contact group dividing section 273F is not comprised, then the correction section (not shown) for correcting the XYθ coordinates will also not be comprised.

As described above, the present invention is exemplified by the use of its preferred Embodiment 1. However, the present invention should not be interpreted solely based on Embodiment 1 described above. It is understood that the scope of the present invention should be interpreted solely based on the claims. It is also understood that those skilled in the art can implement equivalent scope of technology, based on the description of the present invention and common knowledge from the description of the detailed preferred Embodiment 1 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a multi-chip prober for testing a predetermined number of plurality of chips, having an adhesion tape attached on one side thereof, in a state where the chips are cut off from a semiconductor wafer; a contact position correction method thereof; a control program describing a processing order for allowing a computer to execute respective steps of the contact position correction method; and a computer-readable, readable recording medium on which the control program is stored. In the present invention, a large number of probes of a probe card, and electrode pads of a large number of chips, whose positional accuracy after being cut is uneven, can be positioned with accuracy, thus, largely increasing the number of chips for simultaneous contact, and thus increasing the efficiency for the test.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A multi-chip prober for allowing respective electrode pads of a plurality of chips, as inspection subjects, to contact simultaneously with respective tip positions of a plurality of probes, the multi-chip prober comprising:
a moving platform capable of securing the plurality of chips, after being cut from a wafer, on an upper surface thereof, movable in three axial directions, such as X-axis, Y-axis and Z-axis, and rotatable around the Z-axis;
a probe position detecting section for detecting the tip position of the plurality of probes;
a pad position detecting section for detecting a position of the electrode pads of the plurality of chips;
a probe section provided with the plurality of probes, for making contact with the electrode pads; and
a position controlling apparatus for detecting respective positions of the plurality of probe tips and the electrode pads based on respective images from the probe position detecting section and the pad position detecting section, and controlling three axial coordinate positions as well as a rotational position around the Z-axis of the electrode pads on the moving platform based on detected respective positions of the plurality of probe tips and the electrode pads, so that the electrode pads of the chips, as inspection subjects, will correspond to the tip positions of the plurality of probes.

2. A multi-chip prober according to claim 1, further comprising: a probe and pad position detecting section for detecting a position of the electrode pads of the plurality of chips and a tip disposition of the plurality of probes; and a batch angle correcting section for corresponding an arrangement angle of the a plurality of chips to a tip arrangement angle of the plurality of probes.

3. A multi-chip prober according to claim 2, wherein the batch angle correcting section calculates a rotation angle around the Z-axis from a difference (θ1=θ1A−θ1B) between an arrangement angle (θ1A) of the plurality of probes and an arrangement angle (θ1B) of the electrode pads of the plurality of chips, and rotates the moving platform around the Z-axis so as to correspond to the arrangement angle (θ1A) of the plurality of probes.

4. A multi-chip prober according to claim 2, wherein the position controlling apparatus further comprises an individual angle averaging section for correcting a batch angle correction position using an average value of the arrangement angles of the individual chips as inspection subjects.

5. A multi-chip prober according to claim 2, further comprising a horizontal direction position correcting section for using an average value of central coordinates of the plurality of chips as a correction value of an arrangement of the plurality of probes in one direction, calculating a deviation amount between a theoretical value and an actual measurement value of chip spaces in another direction that is perpendicular to the one direction, calculating a deviation amount of probe tip spaces, and using a value obtained by subtracting average values of deviation amounts from respective theoretical values of the chip spaces and the probe tip spaces, as a correction value.

6. A multi-chip prober according to claim 2, further comprising a horizontal direction position correcting section for correcting central coordinates of a center chip, or central coordinates in between central chips, among the plurality of chips as the inspection subjects, and for correcting central coordinates of a center probe, or central coordinates in between central probes, among the plurality of probes, in such a manner to correspond the central coordinates in X and Y directions.

7. A multi-chip prober according to claim 2, further comprising a contact group dividing section for performing division processing on the electrode pads into at least two contact groups of the electrode pads of one or a plurality of chips that are not able to make simultaneous contact, and electrode pads of one or a plurality of the remaining chips, when at least one of the tips of the plurality of probes is not positioned within the range of the electrode pads of the plurality of chips.

8. A multi-chip prober according to claim 2, further comprising a contact group dividing section for performing division processing for positional correction processing of a series of a plurality of contact groups of: electrode pads of one or a plurality of chips that are not able to make simultaneous contact; and electrode pads prior to said electrode pads of one or a plurality of chips and electrode pads after said electrode pads of one or a plurality of chips, when at least one of the tips of the plurality of probes is not positioned within the range of the electrode pads of the plurality of chips.

9. A multi-chip prober according to claim 7, wherein a XYθ coordinate correction is performed on the electrode pads of one or a plurality of the chips that are not able to make simultaneous contact, on which the contact group dividing section has performed the division processing, so that the respective tips of one or a plurality of probes corresponding to the electrode pads will correspond to the electrode pads of one or a plurality of the chips that are not able to make simultaneous contact.

10. A multi-chip prober according to claim 8, wherein a XYθ coordinate correction is performed on the electrode pads of one or a plurality of the chips that are not able to make simultaneous contact, on which the contact group dividing section has performed the division processing, so that the respective tips of one or a plurality of probes corresponding to the electrode pads will correspond to the electrode pads of one or a plurality of the chips that are not able to make simultaneous contact.

11. A contact position correction method of a multi-chip prober, comprising a contact position controlling step of, when electrode pads of a plurality of chips, as inspection subjects, are allowed to make simultaneous contact with tip positions of a plurality of probes, a position controlling apparatus detecting a plurality of probe tip positions of a probe section and each position of the electrode pads of the plurality of chips, as inspection subjects, based on respective images from a probe position detecting section and a pad position detecting section, and controlling three axial coordinate positions as well as a rotational position around the Z-axis of the electrode pads of the plurality of chips on a moving platform, based on detected respective positions of the plurality of probe tip positions and the electrode pads of the plurality of chips, as inspection subjects, so that the electrode pads of the plurality of chips, as inspection subjects, will correspond to the tip positions of the plurality of probes.

12. A contact position correction method of a multi-chip prober according to claim 11, wherein the contact position controlling step comprises:
a probe and pad position detecting step of a probe and pad position detecting section detecting the position of the electrode pads of the plurality of chips and a tip disposition of the plurality of probes; and
a batch angle correcting step of a batch angle correcting section corresponding an arrangement angle of a plurality of chips, as the inspection subjects, to a tip arrangement angle of the plurality of probes.

13. A contact position correction method of a multi-chip prober according to claim 12, wherein the batch angle correcting step calculates a rotation angle around the Z-axis from a difference (θ1=θ1A−θ1B) between an arrangement angle (θ1A) of the plurality of probes and an arrangement angle (θ1B) of the electrode pads of the plurality of chips, and rotates the moving platform around the Z-axis so as to correspond to the arrangement angle (θ1A) of the plurality of probes.

14. A contact position correction method of a multi-chip prober according to claim 12, wherein the contact position controlling step comprises an individual angle averaging step of an individual angle averaging section correcting a batch angle correction position using an average value of arrangement angles of the individual chips as inspection subjects.

15. A contact position correction method of a multi-chip prober according to claim 12, further comprising a horizontal direction position correcting step of a horizontal direction position correcting section using an average value of central coordinates of the plurality of chips as a correction value of an arrangement of the plurality of probes in one direction, calculating a deviation amount between a theoretical value and an actual measurement value of chip spaces in another direction that is perpendicular to the one direction, calculating a deviation amount between a theoretical value and an actual measurement value of probe tip spaces, and using a value obtained by subtracting average values of deviation amounts from respective theoretical values of the chip spaces and the probe tip spaces, as a correction value.

16. A contact position correction method of a multi-chip prober according to claim 12, further comprising a horizontal direction position correcting step of a horizontal direction position correcting section correcting central coordinates of a center chip, or central coordinates in between central chips, among the plurality of chips as the inspection subjects, in X and Y directions so as to be positioned to central coordinates of a center probe, or central coordinates in between central probes, among the plurality of probes.

17. A contact position correction method of a multi-chip prober according to claim 12, further comprising a contact group dividing step of a contact group dividing section performing division processing on the electrode pads into at least two contact groups of the electrode pads of one or a plurality of chips that are not able to make simultaneous contact, and electrode pads of one or a plurality of the remaining chips, when at least one of the tips of the plurality of probes is not positioned within the range of the electrode pads of the plurality of chips.

18. A contact position correction method of a multi-chip prober according to claim 12, further comprising a contact group dividing step of a contact group dividing section performing division processing for positional correction processing of a series of a plurality of contact groups of: electrode pads of one or a plurality of chips that are not able to make simultaneous contact; and electrode pads prior to said electrode pads of one or a plurality of chips and electrode pads after said electrode pads of one or a plurality of chips, when at least one of the tips of the plurality of probes is not positioned within the range of the electrode pads of the plurality of chips.

19. A contact position correction method of a multi-chip prober according to claim 17, further comprising a correcting step of performing a XYθ coordinate correction on the electrode pads of one or a plurality of the chips that are not able to make simultaneous contact, on which the contact group dividing section has performed the division processing, so that the respective tips of one or a plurality of probes corresponding to the electrode pads will correspond to the electrode pads of one or a plurality of the chips that are not able to make simultaneous contact.

20. A computer-readable, readable recording medium on which a control program is stored, the control program describing a processing order for allowing a computer to execute respective steps of the contact position correction method of a multi-chip prober according to claim 11.
